(19) United States
(12) Patent Application Publication
(10) Pub. No.: US 2014/0176175 A1
(43) Pub. Date: Jun. 26, 2014

(54) Dry Catheter RF Tester

(71) Applicant: Volcano Corporation, San Diego, CA (US)

(72) Inventor: Jeffery H. Brown, Valley Center, CA (US)

(73) Assignee: Volcano Corporation, San Diego, CA (US)

(21) Appl. No.: 14/135,084

(22) Filed: Dec. 19, 2013

Related U.S. Application Data
(60) Provisional application No. 61/745,483, filed on Dec. 21, 2012.

(51) Int. Cl. G01R 31/308; G01R 1/07

(52) U.S. Cl. CPC G01R 31/308; G01R 1/07
USPC 324/754.31

(57) ABSTRACT

A method and a system of testing an electrical signal path functionality of a sensing catheter in a dry environment. A variety of test input patterns are generated by an arbitrary near field RF signal generator, transmitted into the sensing catheter disposed in a shielded enclosure. B-mode like images corresponding to the test input patterns are generated and displayed by an imaging system connected to a proximal end of the sensing catheter, and then analyzed by a computer system, as dependent on the frequency, amplitude, and phase of the test input patterns. A determination is made as to whether the sensing catheter retains a desired electrical signal path functionality based on the analysis. The sensing catheter could be a variety of sensing catheters including forward looking catheters, a rotational IVUS catheters, or phased array IVUS catheters.

### CROSS-REFERENCE TO RELATED APPLICATION

The present application claims the benefit of the filing date of provisional U.S. Patent Application No. 61/745,483 filed Dec. 21, 2012. The entire disclosure of this provisional application is incorporated herein by this reference.

### TECHNICAL FIELD

The present disclosure relates generally to intravascular ultrasound (IVUS) imaging system and, more particularly, to a system and method for testing intravascular ultrasound imaging catheters for electrical signal path functionality.

### BACKGROUND

Intravascular ultrasound (IVUS) imaging is widely used in interventional cardiology as a diagnostic tool for assessing a diseased vessel, such as an artery, within the human body to determine the need for treatment, to guide the intervention, and/or to assess its effectiveness. IVUS imaging uses ultrasound echoes to form a cross-sectional image of the vessel of interest. Typically, the ultrasound transducer on an IVUS catheter both emits ultrasound pulses and receives the reflected ultrasound echoes. The ultrasound waves pass easily through most tissues and blood, but they are partially reflected by discontinuities arising from tissue structures (such as the various layers of the vessel wall), red blood cells, and other features of interest. The IVUS imaging system, which is connected to the IVUS catheter by way of a patient interface module (PIM), processes the received ultrasound echoes to produce a cross-sectional image of the vessel where the catheter is located.

There are two types of IVUS catheters in common use today: solid-state (also known as synthetic aperture phased array) and rotational, with each having advantages and disadvantages. Solid-state IVUS catheters use an array of ultrasound transducers (typically 64) distributed around the circumference of the catheter and connected to an electronic multiplexer circuit. The multiplexer circuit selects array elements for transmitting an ultrasound pulse and receiving the echo signal. By stepping through a sequence of transmit-receive pairs, the solid-state IVUS system can synthesize the effect of a mechanically scanned transducer element, but without moving parts. Since there is no rotating mechanical element, the transducer array can be placed in direct contact with the blood and vessel tissue with minimal risk of vessel trauma and the solid-state scanner can be wired directly to the imaging system with a simple electrical cable and a standard detachable electrical connector.

In the typical rotational IVUS catheter, a single ultrasound transducer element fabricated from a piezoelectric ceramic material is located at the tip of a flexible driveshaft that spins inside a plastic sheath inserted into the vessel of interest. The piezoelectric ceramic material has low electrical impedance capable of directly driving an electrical cable connecting the transducer to the imaging system hardware. The transducer element is oriented such that the ultrasound beam propagates generally perpendicular to the axis of the catheter. The fluid-filled sheath protects the vessel tissue from the spinning transducer and driveshaft while permitting ultrasound signals to freely propagate from the transducer into the tissue and back. As the driveshaft rotates (typically at 30 revolutions per second), the transducer is periodically excited with a high voltage pulse to emit a short burst of ultrasound. The same transducer then listens for the returning echoes reflected from various tissue structures. In this case, a single pair of electrical leads (or coaxial cable) is used to carry the transmit pulse from the system to the transducer and to carry the received echo signals from the transducer back to the imaging system where they are assembled into an image by way of a patient interface module (PIM). Then, the IVUS imaging system assembles a two dimensional display of the vessel cross-section from a sequence of several hundred of these ultrasound pulse/echo acquisition sequences occurring during a single revolution of the transducer. An important complication in this electrical interface is the transportation of electrical signals across a rotating mechanical junction. Since the catheter driveshaft and transducer are spinning (in order to scan a cross-section of the artery) and the imaging system hardware is stationary, there must be an electromechanical interface where the electrical signals traverse the rotating junction. In rotational IVUS imaging systems, this problem can be solved by a variety of different approaches, including the use of a rotary transformer, slip rings, rotary capacitors, etc.

Whether using a rotational or a solid-state (phased array) catheter, it is necessary for ensuring optimum performance to test the electrical signal path functionality of the catheter, more particularly, whether it will transmit the electrical signal without impairment or distortion to enable the IVUS devices to produce the right image expected for a particular given input pattern. Such a test may be needed either after finishing manufacturing of them or even during their actual use. The ability for the IVUS devices to produce a correct image depends on the ability of a catheter to receive, transmit and process electrical signals correctly. Any defect in, or malfunctioning of any component parts of a catheter that passes an electrical signal, including the electrical cable, driveshaft, sheath, or the transducer, would end up with producing a distorted or defective image.

The traditional way of testing the electrical signal path functionality of a catheter is a ‘wet’ test, in which a subject catheter is immersed in liquid in a pot that has a phantom object therein. When an ultrasound signal is transmitted through the catheter and an echo signal is collected and transmitted back, it is evaluated on whether a correct image of the phantom in the pot is reproduced. This test method is, however, cumbersome and costly in that it requires preparation of a liquid pot and a phantom object, immersion of a subject catheter into the liquid, and a complicated alignment of the guide wire.

Accordingly, there remains a need to provide quicker and more convenient ways, than the traditional one, to test a catheter, particularly its functionality of transmitting and processing electrical signals, which would save all the hassles and cost associated with the ‘wet’ environment for the traditional test method.

### SUMMARY

Embodiments of the present disclosure provide a method and system for testing whether a sensing catheter retains a desirable electrical path functionality under a dry environment. More specifically, the system applies a radio frequency (RF) signal to the catheter and the associated image generated by the catheter is evaluated to detect any faults in the catheter system.

In one embodiment, a method of testing an electrical signal path functionality of a sensing catheter is provided. The method comprises: providing a test system; generating by a signal generator, a near field RF signal corresponding to a first input pattern; transmitting the first input pattern through the sensing catheter via an antenna; generating, by an imaging system, an image for first input pattern transmitted through the sensing catheter; analyzing, by a computer system, the image based on the first input pattern; and determining whether the sensing catheter retains a desired electrical signal path functionality. The test system provided comprises: a near field RF signal generator; the sensing catheter to be tested, the sensing catheter having distal and proximal ends; an enclosure configured to receive a distal end of the sensing catheter; an antenna disposed in the enclosure, and configured to receive a near field RF signal, and be electrical magnetically coupled to the distal end of the sensing catheter to transmit the near field RF signal therethrough; an imaging system electrically coupled to the proximal end of the sensing catheter and configured to generate an image specific to the near field RF signal transmitted through the sensing catheter; and a computer system electrically coupled to the imaging system and the signal generator and configured to analyze the image generated by the imaging system.

In one embodiment, the system for testing an electrical signal path functionality of a sensing catheter having distal and proximal ends is provided. The test system comprises: a signal generator of a near field radio frequency (RF) signal; an enclosure configured to receive the distal end of the catheter to be tested; an antenna disposed in the enclosure for receiving the near field RF signal and converting the same into an electromagnetic wave, an imaging system capable of being electrically coupled to the proximal end of the sensing catheter and configured to generate an image specific to the near field RF signal; and a computer system electrically coupled to the imaging system and the signal generator, where the computer system is configured to analyze the image based on the near field RF signal for determining an electrical signal path functionality of the sensing catheter.

In an embodiment, the image generated by the imaging system is a two-dimensional image analogous to the B-mode image generated by an ultrasound. In some embodiments, the signal generator may be an arbitrary function generator. The enclosure may be shielded from disturbance of external electromagnetic field. The sensing catheter may be either a rotational catheter or a phased array catheter.

In some embodiment of the method, the near field RF signals may be transmitted to the sensing catheter by means of an antennae disposed adjacent the distal end of the sensing catheter. Also in some embodiment, the image generated by the imaging system may be a two-dimensional image analogous to the B-mode image generated by an ultrasound. In some embodiments, the signal generator may be an arbitrary function generator. The enclosure may be shielded from disturbance of external electromagnetic field. The sensing catheter may be either a rotational catheter or a phased array catheter.

In some embodiments, the method may further comprise generating a second input pattern by the signal generator and repeating the afore-mentioned steps of transmitting, generating, and analyzing for the second input pattern. The second input pattern may be generated by varying one or more of the frequency, phase, and amplitude of the near field RF signal for the first input pattern based on the image obtained by the imaging system for the first test pattern. In one embodiment, the determination of whether the sensing catheter retains a desirable electrical signal path functionality may be made by a computer program installed in the computing system, but in another embodiment, by a human judgment. In another embodiment, the determination of whether the sensing catheter retains a desired electrical signal path functionality may be made in consideration of frequency characteristics of the sensing catheter.

In another embodiment, a method of determining whether a sensing catheter retains a desirable electrical signal path functionality is also provided. The method comprises: generating near field RF signals corresponding to a variety of random input test patterns; receiving the near field RF signals by an antenna; transmitting electrical signals corresponding to the near field RF signals received by the antenna through the sensing catheter; generating images corresponding to the respective input test patterns from the transmitted electrical signals; and analyzing the images in view of the input test patterns for determining whether the sensing catheter retains the desirable electrical signal path functionality. In some embodiments, generation of near field RF signals may be achieved by varying one or more of the frequency, phase, and amplitude of a near field RF signal.

Additional aspects, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 is a schematic diagram of a method performed for testing an electrical signal path functionality of a sensing catheter according to an embodiment of the present disclosure;

FIG. 2 is a test system with the components used for testing an electrical signal path functionality of a sensing catheter according to an embodiment of the present disclosure;

FIG. 3 is a screen showing settings for an example test input pattern generated by a near field RF signal generator to be transmitted to a sensing catheter according to an embodiment of the present disclosure;

FIG. 4 is an example B-mode image generated by an imaging system for the test input pattern transmitted through a sensing catheter according to an embodiment of the present disclosure; and

FIG. 5 illustrates an example B-mode image generated by a defective catheter.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

The satisfactory performance of an IVUS imaging catheter, whether it is a rotational or phased array type, depends on, among others, its capability of transmitting the echo signal, typically ultrasound, picked from a sensing tissue or organ by a distal end of a catheter, to an imaging system for generating and displaying the images of the sensing tissue or organ. To ensure that a catheter has a satisfactory electrical signal transmission functionality to generate a correct image of the real human intravascular organ or tissue, the present disclosure contemplates several embodiments for a method of testing a sensing catheter in a ‘dry’ environment without the hassles involved with a wet environment under which the traditional test is typically performed with acoustic sources such ultrasonic waves.

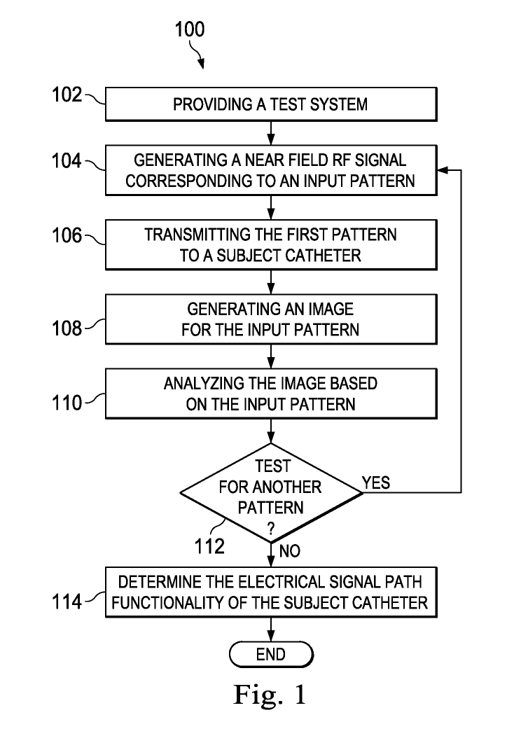

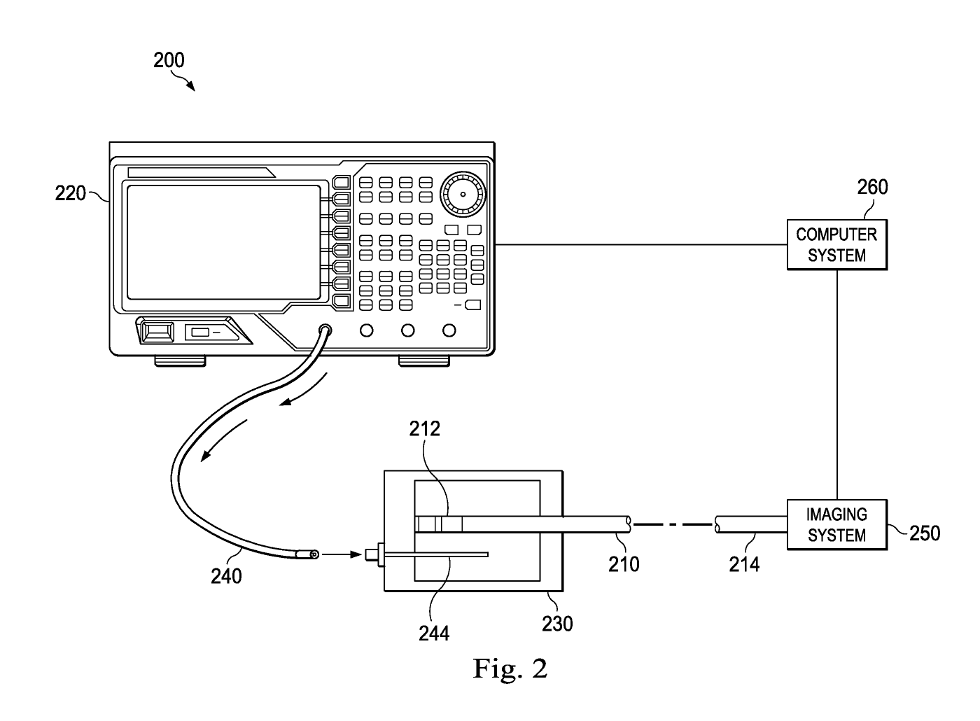

Now referring to the figures, FIG. 1 shows a schematic diagram of a method 100 performed for testing an electrical signal path functionality of a sensing catheter in an embodiment of the present disclosure and FIG. 2 shows a test system 200 with various components used for performing such a method in an embodiment of the present disclosure.

Now referring to FIG. 1, the first step of the method 100, the step 110, is to provide a test system 200. When referring to the components of the test system 200, the reference numeral is taken from FIG. 2 hereinafter. The test system 200 comprises, in an embodiment of the present disclosure, a sensing catheter 210 to be tested, a signal generator 220, a shielded enclosure 230, a cable 240 extended between the signal generator 220 and an antenna 244 disposed with the enclosure, an antenna 244, an imaging system 250, and a computer system 260. Herein, the word ‘provide’ is used in a broad sense encompassing ‘purchasing’, ‘preparing’, ‘manufacturing’, ‘arranging,’ or ‘making in order’ the components of the test system 200. The sensing catheter 210 may be either of a standard rotational or phased array IVUS catheter. The IVUS catheter 210 has a distal end 212 and an opposing proximal end 214, and typically may include one or more ultrasound transducers, depending on the array type of the sensing catheter 210, along with its associated circuitry mounted near the distal tip of the catheter, an electrical cable (transmission line), and the appropriate electrical connector at the proximal end to be coupled to a patient interface module (PIM), which may be connected to the imaging system 250. If the sensing catheter 210 is a piezoelectric micromachined ultrasound transducer (PMUT) rotational IVUS catheter, it may include an imaging core and an outer catheter/sheath assembly. The imaging core may include a flexible drive shaft that is terminated at the proximal end by a rotational interface providing electrical and mechanical coupling to the PIM. The distal end of the flexible drive shaft of the imaging core is coupled to a transducer housing containing the PMUT and associated circuitry. In one aspect, the associated circuitry includes an ASIC. The catheter/sheath assembly may further include a hub that supports the rotational interface and provides a bearing surface and a fluid seal between the rotating and non-rotating elements of the catheter assembly.

The signal generator 220 generates, in an embodiment of the present disclosure, near field RF signals of various frequencies, amplitudes, and phases corresponding to particular, but generally arbitrary patterns or waveforms. The shielded enclosure 230 is configured to receive a distal end 212 of the sensing catheter 210. The antenna 244 is disposed in the shielded enclosure 230, and configured to receive the near field RF signals transmitted from the signal generator 220 through cable 240. The antenna transmits corresponding RF electromagnetic waves that are wirelessly received by the distal end of the sensing catheter to the internal catheter sensors, processors and circuits then transmit corresponding signals therethrough. The imaging system 250 is electrically coupled to the proximal end 214 of the sensing catheter 210 and configured to generate an image specific to the near field RF signal transmitted through the sensing catheter 210. The computer system 260 is electrically coupled to the imaging system and also to the signal generator to analyze various images generated by the imaging system 250 in response to the RF signals transmitted thereto through the sensing catheter 210. The roles and functions for each component of the test system 200 according to various embodiments of the present disclosure will be described more in detail hereinafter while describing the subsequent steps of the method 100 schematically shown in FIG. 1.

Now referring back to FIG. 1, at step 104, a near field RF signal corresponding to a specific test input pattern is generated by the signal generator 220. The signal generator 220, which is also known as a function generator, a RF or microwave signal generator, a pitch generator, an arbitrary waveform generator, a digital pattern generator or frequency generator is an electronic device that generates repeating or non-repeating electronic signals in either the analog or digital domains. In one embodiment of the present disclosure, the signal generator 220 may be an arbitrary function or waveform generator that is used for higher-end design and test applications. The arbitrary waveform generators are sophisticated signal generators which allow the user to generate arbitrary waveforms, including more regular waveforms such as a sine wave, a sawtooth, step (pulse), square, or triangular waveform, within published limits of frequency range, accuracy, and output level. The arbitrary waveform generators allow the user to specify a source waveform in a variety of different ways.

The arbitrary waveform generators may use an electronic oscillator, a circuit capable of creating a repetitive waveforms and using digital signal processing to synthesize waveforms, or a digital to analog converter, or DAC, to produce an analog output. Further, the arbitrary waveform generator 220 may include some sort of modulation function, such as amplitude modulation (AM), frequency modulation (FM), phase modulation (PM), and pulse modulation, and also a built-in attenuator which makes it possible to vary the signal's output power.

In one embodiment, the arbitrary waveform generators 220 may use a RF (radio frequency) or microwaves for testing the sensing catheter 210. Typically, the RF frequency ranges from a few kHz to 6 GHz, while microwaves cover a much wider frequency range, from less than 1 MHz to at least 20 GHz. Some RF generators go as high as 70 GHz with a direct coaxial output, and up to hundreds of GHz when used with external waveguide source modules. The RF signal generator 220 can be either an analog or a vector signal generator.

In another embodiment, the arbitrary waveform generators 220 may generate near field RF signals. The near field RF radiation has proved useful in applications such as radio-frequency identification (RFID) and near field communications (NFC). The near field of an electromagnetic radiation, while depending on the types of antenna and applications, is typically less than one wavelength (λ) from the antenna, and may be given by:

λ/2π=0.159λ

For instance, for a radio wave with frequency of 900 MHz, the near field would be within about 2 inches from an antenna that generates and transmits the radio wave, and for a radio wave with frequency of 13.5 MHz, the near field would be within about 11.5 feet.

Now referring back to FIG. 1, at step 106, the near field RF signal, which has been generated by the signal generator 220, passed through cable 240 to antenna 244 and transmitted wirelessly via the transmission antenna 244 enclosed in the signal generator 220. In the embodiments of the present disclosure that utilizes near field RF signals for probing the electrical signal path functionality of the sensing catheter 210, the distance between the near field RF signal antenna 244, and the catheter distal end 212, should be appropriately adjusted depending on the particular frequency ranges of RF signals for effective reception of the signals by the catheter. The antenna 240 may be fixedly located adjacent a side of the enclosure 230 that is opposite the side where the inlet for admitting the catheter 210. The antenna 240 utilized here in the present disclosure may be any typical antenna that is capable of wirelessly transmitting the near field RF signals of various patterns or waveforms generated from the signal generator 220. The electrical signals specific to the various RF signal patterns or waveforms are received wirelessly by the catheter and transmitted through the sensing catheter 210, more particularly, through an electrical cable (not shown) contained within the sheath of the catheter 210.

The enclosure 230 is a housing or a holder for holding a distal end 212 of the sensing catheter 210 as well as the antenna 240. It is designed to receive the distal end 212 of the sensing catheter 210 through, for instance, a hole or inlet (not shown) defined at one side, and securely hold it therein. In an embodiment, the enclosure 230 may be designed and appropriately made of a suitable material so that it may be effectively shielded from any potential disturbance from external electromagnetic fields, which may cause an electromagnetic interference with the near field RF signals. The design and materials for achieving such electromagnetic shielding are well known in the art, and not described herein further.

Referring back to FIG. 1, at step 108, the imaging system 250 generates an image for the electrical signals corresponding to specific test input pattern. The imaging system 250 is electrically coupled with the proximal end 214 of the sensing catheter 210 through a connector (not shown) that is compatible with either a rotational catheter or a phased array catheter. After receiving the electrical signals specific to the RF signals of various patterns or waveforms transmitted through the catheter 210, the imaging system 250 generates, and displays on its monitor, two dimensional images corresponding to the specific respective input patterns or waveforms generated by the arbitrary function generator 220. The two dimensional images generated and displayed by the imaging system 250 may be analogous to the conventional B-mode images generated by an ultrasound sonography. In one embodiment, the imaging system 250 may be a typical IVUS imaging system, such as Volcano S5x, comprising a patient interface module (PIM) compatible with either a rotational catheter or a phased array catheter, a console or processing system, and a monitor to display the images generated by the console.

Again, referring back to FIG. 1, at step 110, the images generated by the imaging system 250 are analyzed by the computer system 260, based on the specific test input RF signal pattern generated by the signal generator 220. The computer system 260 is electrically coupled, either by wire or wirelessly, with both the imaging system 250 and the signal generator 220 for analyzing the images displayed on the screen of the imaging system 250. The computer system 260 may be a typical PC or a server that includes a bus or other communication mechanism for communicating information data, signals, and information between various components (not shown). Components may include an input component such as a keypad, keyboard, or a touch screen, an output component, such as a display screen, a transceiver or network interface for transmitting and receiving signals between the computer and other devices, such as the imaging system 250 and the signal generator 220. In one embodiment, the transmission between the signal generator 220 and the computer system 260 may be wireless, although other transmission mediums like a conventional wire and methods may also be suitable. A processor, which can be a micro-controller, digital signal processor (DSP), or other processing component, processes these various signals, such as for display on the computer system 260 or transmission to other devices via a communication link. Components of the computer system 260 also include a system memory component (e.g., RAM), a static storage component (e.g., ROM), and/or a disk drive.

By utilizing the processor and other components executing one or more sequences of instructions contained in a system memory component, the computer system 260 generates ‘pass’ image(s) corresponding to a specific RF signal input pattern generated from the signal generator 220. Further, at step 110, the computer system 260 analyzes the images produced by the imaging system 250 while comparing them with the ‘pass’ images. The logic for performing such operations may be encoded in a computer readable medium, which may refer to any medium that participates in providing instructions to the processor for execution. Such a medium may take many forms, including but not limited to, non-volatile media such as optical or magnetic disks, volatile media such as dynamic memory and system memory component, and transmission media such as coaxial cables, copper wire, and fiber optics, including wires that comprise bus. In one embodiment, the logic may be encoded in non-transitory computer readable medium including a floppy disk, flexible disk, hard disk, magnetic tape, any other magnetic medium, CD-ROM, any other optical medium, punch cards, paper tape, any other physical medium with patterns of holes, RAM, PROM, EEPROM, FLASH-EEPROM, any other memory chip or cartridge, or any other medium from which a computer is adapted to read. In one example, transmission media may take the form of acoustic or light waves, such as those generated during radio wave, optical, and infrared data communications. In another embodiment of the present disclosure, the computer system 260 may comprise a plurality of computer sub-systems coupled by communication link to perform instruction sequences to practice the present disclosure in coordination with one another.

The analysis of each image generated from the signal generator 220, at step 110, is performed by the computer system 260. The analysis is performed based on the particular near field RF signal pattern, which resulted in the image being analyzed. A suitably written program, and one or more sequences of instructions contained in system memory component of the computer system 260 enables such analysis. Before analyzing the images generated from the signal generator 220, the computer system 260 creates one or more similar responsive ‘pass’ image(s) that are expected to be produced by the imaging system 250 when the sensing catheter 210 performs a satisfactory transmission of the electrical signals for a specific RF input pattern. The creation of a ‘pass’ image(s) may be implemented by a suitable program in the computer system 260. For generating the ‘pass’ image(s), the computer system 26 needs to receive all physical characteristic of the specific input pattern or waveform, including the RF frequency, amplitude and phases, from the signal generator 220. The computer system 260 may further utilize the specifications of the particular sensing catheter 210 such as its impedance, length, diameter, and composing material of the electrical cable, and so on. When the imaging system 250 generates and displays an image for a specific input pattern on its monitor or a separate screen of the computer system 260, the computer system 260 compares the image with the corresponding ‘pass’ image it created.

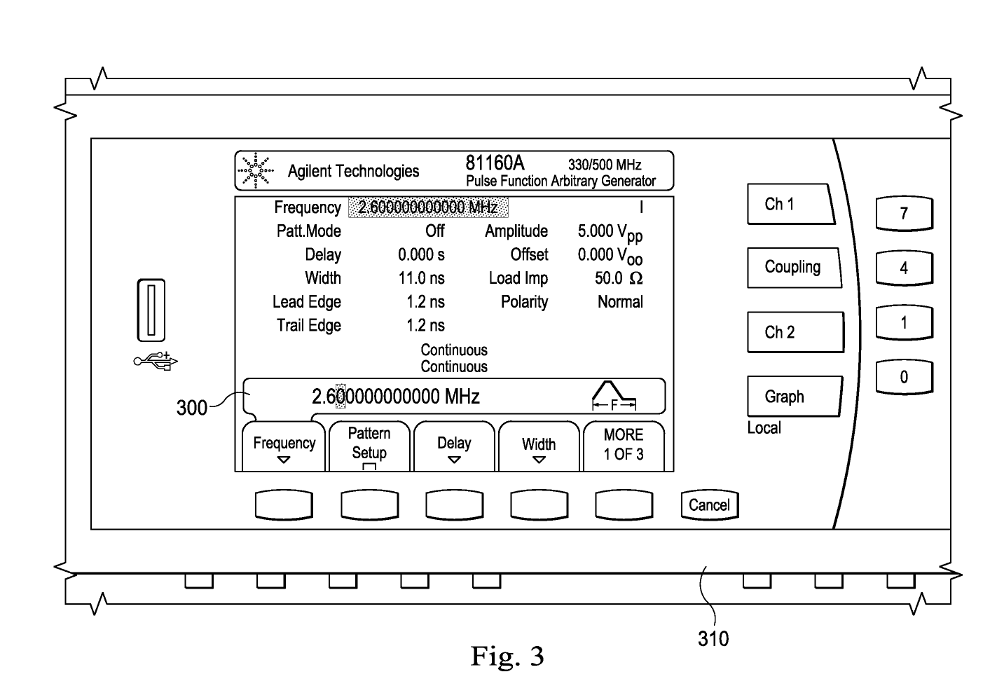

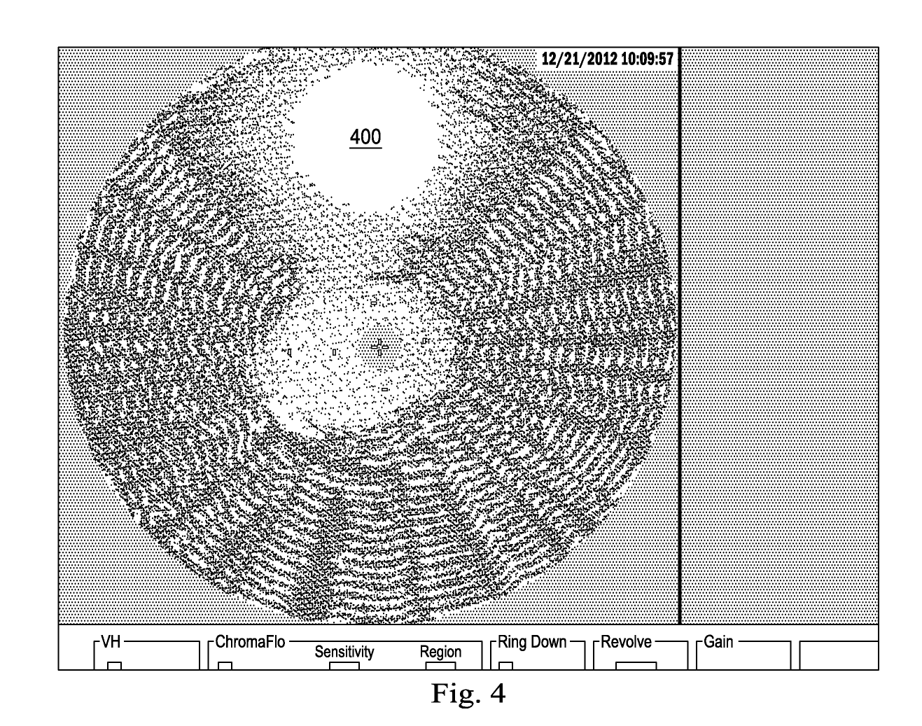

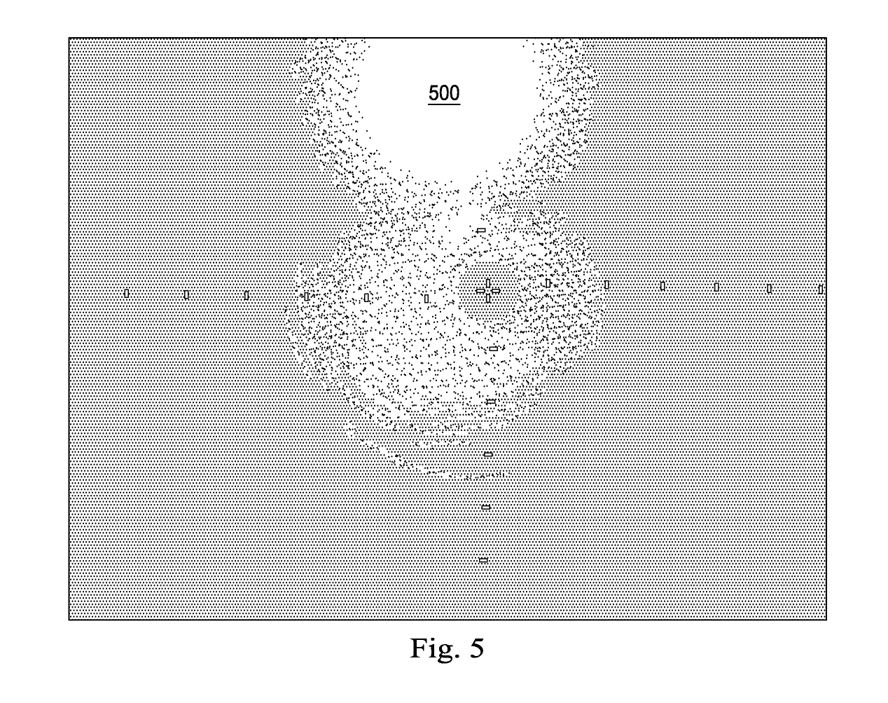

Referring now to FIG. 3, there is shown a pulse generator suitable 310 for providing RF input patterns to the test system shown in FIG. 2. In the illustrated embodiment, the pulse generator is an Agilent Technologies 81160A Pulse Function Arbitrary Generator. Although many different RF test patterns may be utilized with the present disclosure, the example shown in FIG. 3 has a 2.6 MHz frequency with a 5 V peak to peak voltage with an 11 ns pulse width. Additional details of the waveform are set forth in the screen shot 300 shown in FIG. 3. When the example RF waveform is applied to the catheter in FIG. 2 via the antenna, the B mode output image of the catheter is shown in FIG. 4. As can be seen, the output B-mode image has a uniform appearance. From the appearance of the output B-mode image a user, or a computer system utilizing image recognition algorithms, can determine whether the catheter components are properly assembled to provide a continuous signal path. Thus, the image 400 of FIG. 4 represents a “pass” image in terms of the quality of the image generated by the catheter in response to the input RF waveform. In contrast, the irregular image 500 shown in FIG. 5 represents a “fail” image when received from the catheter in response to the applied RF signal.

In many cases, the electrical path functionality of a sensing catheter may be frequency sensitive. Therefore, even if the image generated by the signal generator 220 may, or may not match the specific ‘pass’ image corresponding to a specific pattern with a specific frequency, it may be necessary to examine the response of the sensing catheter to another pattern, or multiple patterns of different frequencies before a final determination is made as to whether as a whole the sensing catheter retains a desired electrical signal path functionality. In one embodiment, the method 100 may further include generating another, sometimes, multiple input test patterns by varying the frequency of the near field RF signals at the signal generator 220 to probe the frequency characteristic of the sensing catheter's response to the injected RF signal. In another embodiment, the variation of the pattern may be achieved by varying the amplitude and/or the phase, instead of or in addition to the frequency to further examine the amplitude or phase dependent behavior of the sensing catheter's the electrical signal path functionality. Therefore, at step 112, the tester may ask whether another test input pattern needs to be generated. If there is a need, the method 100 may repeat the steps from 104 to 110. With applying variable RF stimulus from the signal generator 220, a variety of distinct images may be generated and displayed by the imaging system 250. Then, the computer system 260 may compare each image with the corresponding ‘pass’ image to examine the electrical signal path functionality of the sensing catheter as depending on the frequency, amplitude, or phase of the injected RF signals.

After performing multiple analyses, in an embodiment, for the images displayed by the imaging system 250, while examining the various responses of the sensing catheter 210 to the varying RF input patterns, then lastly at step 114, a determination is made as to whether the sensing catheter 210 retains a desired electrical signal path functionality. This determination may be made based on the individual or comprehensive results from the multiple analyses for a variety of input RF signal patterns performed at step 110. Depending upon the particular applications of the sensing catheter, satisfactory matching of the generated images with the ‘pass’ image in all frequency ranges may not be necessary for the sensing catheter to ‘pass’ the test. For instance, the sensing catheter may reveal a satisfactory electrical signal path functionality only in a specific, relatively narrow range of frequencies that are of particular importance in practical applications, and still be considered to be acceptable for actual medical use. Also, the determination at step 114 may be made either by human tester by considering and judging from the multiple analyses performed by the computer system 260, or by a computer program automatically. In the latter case, the computer system 260 would make a decision, following the algorithm of the program, from the evaluation of the multiple analysis results, and all pre-entered factors/criteria for decision making, including low and high ends of the acceptable electrical path functionality.

There are a number of advantages with the test method and system in the present disclosure. By performing the test in a ‘dry’ environment without acoustic stimulus, the test method in the present disclosure avoids the inconveniences, hassles, and cost, associated with the traditional ‘wet’ test, which include the need of preparing a liquid pot, manufacturing a phantom object, sealing the distal ends of a catheter in the pot, and aligning guide wires. By utilizing simple, conventional instruments such as a RF signal generator with a coupled antenna, the test method in the present disclosure is easy to practice and saves cost and time. Further, from generating, controlling, and evaluating a variety of test input RF patterns by easily adjusting the frequency, amplitude, and phase of the applied signal at will, the test method in the present disclosure enables to quickly screen for the sensing catheters with any suspected ingress, weak or dead elements in the sensing catheters, or other frequency-sensitive signal path impairment including discontinuities in the transmission lines. The applications of the test method in the present disclosure could be broad. It may be used for evaluation of catheter system frequency response for both the rotational and phased array types, electrical cable bandwidth test, detection of intermittent during tortuousity testing, evaluation of electromagnetic interference (EMI) susceptibility, detection of ingress induced signal degradation, failure analysis investigation, creation of synthetic images without an acoustic source, or evaluation of rotational and rate stability.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

What is claimed is:

1. A system for testing an electrical signal path functionality of a sensing catheter having distal and proximal ends, the system comprising:
a signal generator of a near field radio frequency (RF) signal;
an enclosure configured to receive the distal end of the sensing catheter;
an antenna disposed in the enclosure for receiving the near field RF signal and converting the same into an electromagnetic signal;
an imaging system capable of being electrically coupled to the proximal end of the sensing catheter and configured to generate an image specific to the near field RF signal; and
a computer system electrically coupled to the imaging system and the signal generator, wherein the computer system is configured to analyze the image based on the near field RF signal for determining an electrical signal path functionality of the sensing catheter.

2. The system of claim 1, further comprising a sensor disposed adjacent the distal end of the sensing catheter for transmitting the near field RF signal thereto.

3. The system of claim 1, wherein the image generated by the imaging system is a B-mode image.

4. The system of claim 1, wherein the signal generator is an arbitrary function generator.

5. The system of claim 1, wherein the enclosure is shielded from disturbance of external electromagnetic field.

6. A method of testing an electrical signal path functionality of a sensing catheter, comprising:
providing a test system comprising:
a near field RF signal generator;
a sensing catheter to be tested, the sensing catheter having distal and proximal ends;
an enclosure configured to receive a distal end of the sensing catheter;
an antenna disposed in the enclosure, and configured to receive a near field RF signal, and transmit the near field RF signal within the enclosure;
an imaging system electrically coupled to the proximal end of the sensing catheter and configured to generate an image specific to the near field RF signal transmitted through the sensing catheter; and
a computer system electrically coupled to the imaging system and the signal generator and configured to analyze the image generated by the imaging system;
generating, by the signal generator, a near field RF signal corresponding to a first input pattern;
transmitting the first input pattern through the sensing catheter via the antenna;
generating, by the imaging system, an image for the first input pattern transmitted through the sensing catheter;
analyzing, by the computer system, the image based on the first input pattern; and
determining whether the sensing catheter retains a desired electrical signal path functionality.

7. The method of claim 6, wherein the near field RF signal is transmitted to the sensing catheter by means of a sensor disposed adjacent the distal end of the sensing catheter.

8. The method of claim 6, further comprising:
generating a second input pattern by the signal generator by varying one or more of the frequency, phase, and amplitude of the near field RF signal for the first input pattern; and
repeating the steps of transmitting, generating, and analyzing for the second input pattern.

9. The method of claim 8, wherein the near field RF signal for the first input pattern is varied based on the image for the first pattern.

10. The method of claim 8, wherein the determination of whether the sensing catheter retains a desired electrical signal path functionality is made in consideration of frequency characteristics of the sensing catheter.

11. The method of claim 6, wherein the enclosure is shielded from disturbance of external electromagnetic field.

12. The method of claim 6, wherein the image generated by the imaging system is a B-mode image.

13. The method of claim 6, wherein the signal generator is an arbitrary function generator.

14. The method of claim 6, wherein the sensing catheter is a rotational catheter.

15. The method of claim 6, wherein the sensing catheter is a phased array catheter.

16. The method of claim 6, wherein the determination of whether the sensing catheter retains a desired electrical signal path functionality is made by a computer program installed in the computing system.

17. A method of determining whether a sensing catheter retains a desirable electrical signal path functionality, comprising:
generating near field RF signals corresponding to a variety of random input test patterns near a sensing component of a sensing catheter;
receiving output signals from the catheter based on the RF signals;
generating images corresponding to the respective input test patterns from the transmitted output signals; and
analyzing the images in view of the input test patterns for determining whether the sensing catheter retains the desirable electrical signal path functionality.

18. The method of claim 17, wherein the generating near field RF signals includes varying one or more of the frequency, phase, and amplitude of a near field RF signal.

19. The method of claim 17, wherein the sensing catheter is a rotational catheter.

20. The method of claim 17, wherein the sensing catheter is a phased array catheter.
